(19) United States
(12) Patent Application Publication
(10) Pub. No.: US 2026/0319011 A1
(43) Pub. Date: Oct. 15, 2026

(54) APPARATUS AND METHOD FOR DIAGNOSING A BATTERY

(71) Applicants: HYUNDAI MOTOR COMPANY, Seoul (KR); KIA CORPORATION, Seoul (KR)

(72) Inventors: Ju Seok Kim, Hwaseong-si (KR); Sang Do Park, Hwaseong-si (KR); Ji Eun Hwang, Hwaseong-si (KR); Sang Jin Lee, Hwaseong-si (KR)

(73) Assignees: HYUNDAI MOTOR COMPANY, Seoul (KR); KIA CORPORATION, Seoul (KR)

(21) Appl. No.: 19/385,906

(22) Filed: Nov. 11, 2025

(30) Foreign Application Priority Data
Apr. 10, 2025 (KR) 10-2025-0046952

(51) Int. Cl. G01R 31/392; G01R 31/3835; G01R 31/396; H01M 10/42

(52) U.S. Cl. CPC G01R 31/392; G01R 31/3835; G01R 31/396; H01M 10/4285; H01M 2220/20

(57) ABSTRACT

A battery diagnosis apparatus for diagnosing a battery status, which includes a memory that stores a first diagnosis criterion index set for a battery durability diagnosis and a second diagnosis criterion index set for a battery safety diagnosis, and a processor that diagnoses a battery status based on the first diagnosis criterion index and the second diagnosis criterion index. The processor obtains data of a battery to be diagnosed, checks a distribution of State Of Health parameters and an inter-cell voltage deviation from the data to perform the battery durability diagnosis based on the first diagnosis criterion index, obtains data corresponding to a plurality of preset safety diagnostic items from the battery to be diagnosed, performs the battery safety diagnosis based on the second diagnosis criterion index, and determines a final diagnosis level of the battery status based on the battery durability diagnosis and the battery safety diagnosis.

### CROSS-REFERENCE TO RELATED APPLICATION

This application claims the benefit of priority to Korean Patent Application No. 10-2025-0046952, filed in the Korean Intellectual Property Office on Apr. 10, 2025, the entire contents of which are incorporated herein by reference.

### TECHNICAL FIELD

The present disclosure relates to a battery diagnosis apparatus and method, and more particularly, relates to a technology capable of classifying and diagnosing a battery from a durability perspective and a safety perspective to determine a final diagnosis level of a battery status.

### BACKGROUND

In general, as the distribution of lithium-ion batteries increases, battery abnormality diagnosis technology is being actively developed to prevent fire accidents caused by battery defects or misuse in advance.

Current battery abnormality diagnosis technology may diagnose battery abnormalities by utilizing various data obtained from the battery, and may diagnose battery abnormalities by setting a specific calculation value as a threshold value, and when the data obtained from the battery exceeds the set threshold value, the battery may be diagnosed as abnormal.

However, it is difficult to determine whether a battery is truly defective or needs maintenance through a specific signal before a problem occurs due to an electrochemical reaction.

Vehicles diagnosed with abnormal battery status are protocolized to be brought into a service center and then undergo a precise diagnosis and other appropriate maintenance measures. Therefore, even if the vehicle battery is not truly defective, when a customer's vehicle is brought into a service center, a corresponding customer response is required, and there is a problem that quality costs increase as misdiagnoses increase.

To minimize these field issues, when the diagnosis criteria range is set narrowly, the golden hours to prevent the field issues may be missed, and conversely, when the diagnosis criteria range is set wide, quality costs due to overdiagnosis may occur.

### SUMMARY

In view of the foregoing, the development of a battery diagnosis apparatus that may set a wide diagnosis criteria range while also setting a response strategy for each section to flexibly respond to customers and reduce quality costs due to overdiagnosis is required.

The present disclosure has been made to solve the above-mentioned problems occurring in the prior art while advantages achieved by the prior art are maintained intact.

An aspect of the present disclosure provides a battery diagnosis apparatus and method capable of diagnosing a battery status based on a first diagnosis criterion index set for battery durability diagnosis and a second diagnosis criterion index set for battery safety diagnosis, thereby setting a wide diagnostic criteria range and thereby setting a response strategy for each diagnosis section, and enabling customer responses flexible and reducing quality costs due to overdiagnosis.

The technical problems to be solved by the present disclosure are not limited to the aforementioned problems, and any other technical problems not mentioned herein should be clearly understood from the following description by those having ordinary skill in the art to which the present disclosure pertains.

According to an aspect of the present disclosure, a battery diagnosis apparatus includes a memory that stores a first diagnosis criterion index set for a battery durability diagnosis and a second diagnosis criterion index set for a battery safety diagnosis, and a processor that diagnoses a battery status based on the first diagnosis criterion index and the second diagnosis criterion index.

According to an embodiment, the processor may obtain data of a battery to be diagnosed, check a distribution of State of Health (SOH) parameters and an inter-cell voltage deviation from the data to perform the battery durability diagnosis based on the first diagnosis criterion index, obtain data corresponding to a plurality of preset safety diagnostic items from the battery to be diagnosed, perform the battery safety diagnosis based on the second diagnosis criterion index, and determine a final diagnosis level of the battery status based on the battery durability diagnosis and the battery safety diagnosis.

According to an embodiment, the processor may obtain cloud data including vehicle mileage-specific SOH (State Of Health) data of the battery to be diagnosed, when the data of the battery to be diagnosed is obtained, or in obtaining the data of the battery to be diagnosed, and when a diagnosis request of the battery is received or based on a diagnosis request of the battery being received.

According to an embodiment, the processor may perform a first determination by first determining whether vehicle mileage-specific SOH data of the battery to be diagnosed is distributed within an average SOH percentile range by vehicle mileage when the battery durability diagnosis is performed, may perform a second determination by secondarily determining a status of an inter-cell voltage deviation of the battery to be diagnosed (e.g., whether an inter-cell voltage deviation of the battery to be diagnosed is abnormal) based on the first diagnosis criterion index and based on whether the vehicle mileage-specific SOH data is distributed within the average SOH percentile range by the vehicle mileage (or when the vehicle mileage-specific SOH data is not distributed within the average SOH percentile range by the vehicle mileage), and may calculate or determine a battery durability level based on the results of the first and second determinations to perform the battery durability diagnosis based on the calculated or determined battery durability level.

According to an embodiment, the processor may, in performing the first determination, determine the battery durability level as a condition-satisfying deterioration level based on the vehicle mileage-specific SOH data being distributed within the average SOH percentile range by the vehicle mileage.

According to an embodiment, the processor may, based on the vehicle mileage-specific SOH data being distributed beyond the average SOH percentile range by the vehicle mileage, determine the battery durability level as a condition-failing deterioration level based on the first diagnosis criterion index including a plurality of preset condition-failing deterioration criterion indices to perform the second determination

According to an embodiment, in determining that the battery durability level as the condition-failing deterioration level, the processor may determine whether the inter-cell voltage deviation of the battery to be diagnosed fails to satisfy a predetermined condition based on the vehicle mileage-specific SOH data being distributed beyond the average SOH percentile range by the vehicle mileage, determine the battery durability level as a condition-failing deterioration initial level based on the inter-cell voltage deviation satisfying a predetermined inter-cell voltage deviation condition, determine whether the inter-cell voltage deviation is included in a first condition-failing deterioration criterion index among the plurality of preset condition-failing deterioration criterion indices based on the inter-cell voltage deviation failing to satisfy the predetermined inter-cell voltage deviation condition, determine the battery durability level as a condition-failing deterioration mid-term level based on the inter-cell voltage deviation being included in the first condition-failing deterioration criterion index, determine whether the inter-cell voltage deviation is included in a second condition-failing deterioration criterion index among the plurality of preset condition-failing deterioration criterion indices based on the inter-cell voltage deviation being beyond the first condition-failing deterioration criterion index, and determine the battery durability level as a condition-failing deterioration terminal level based on the inter-cell voltage deviation being included in the second condition-failing deterioration criterion index.

According to an embodiment, in determining the battery durability level, the processor may check a Battery Management System (BMS) estimated SOH value, and determine the battery durability level based on a formula including L=100*(SOH−70)/30 where, L is the battery durability level and is based on Beginning Of Life (BOL) 100% to End Of Life (EOL) 70%.

According to an embodiment, the processor may obtain data corresponding to the plurality of preset safety diagnostic items when the battery safety diagnosis is performed, may determine whether the obtained data corresponding to the plurality of preset safety diagnostic items satisfies diagnostic conditions for the plurality of preset safety diagnostic items based on the second diagnosis criterion index, may determine a battery safety level based on one or more safety diagnostic items that do not satisfy (fail to satisfy) the diagnostic conditions, and may perform the battery safety diagnosis based on the determined battery safety level.

According to an embodiment, the processor may determine whether first diagnostic conditions for an over-temperature diagnostic item, an over-voltage diagnostic item, and a low-voltage diagnostic item among the plurality of preset safety diagnostic items is satisfied when the battery safety level is determined; may first determine the battery safety level based on the number of one or more safety diagnostic items that are not satisfied with (or fail to satisfy) the first diagnostic condition, may determine whether a second diagnostic condition for a cell voltage change item during charging is satisfied and a third diagnostic condition for an inter-cell voltage deviation item during charging is satisfied when all of the first diagnostic conditions are satisfied or based on all of the first diagnostic conditions being satisfied,, and may secondly determine the battery safety level based on one or more safety diagnostic items that are not satisfied with (or fail to satisfy) the second and third diagnostic conditions.

According to an embodiment, the processor may determine the final diagnosis level of the battery status as a first level to output a notification for normal battery use (or condition-satisfying battery use) when the final diagnosis level of the battery status is determined and when both the battery durability diagnosis and the battery safety diagnosis are at a normal deterioration level (or based on the battery durability diagnosis and the battery safety diagnosis being at a condition-satisfying deterioration level), may determine the final diagnosis level of the battery status as a second level to output a notification for battery diagnosis reservation when the battery durability diagnosis is at an abnormal deterioration level and the battery safety diagnosis is at the normal deterioration level or an abnormal deterioration initial level (or based on the battery durability diagnosis being at a condition-failing deterioration level and the battery safety diagnosis being at the condition-satisfying deterioration level or a condition-failing deterioration initial level), may determine the final diagnosis level of the battery status as a third level to output a notification for battery immediate diagnosis when the battery durability diagnosis is at the abnormal deterioration level and the battery safety diagnosis is at an abnormal deterioration mid-term level (or based on the battery durability diagnosis being at the condition-failing deterioration level and the battery safety diagnosis being at a condition-failing deterioration mid-term level), and may determine the final diagnosis level of the battery status as a fourth level to output a notification for battery immediate replacement when the battery durability diagnosis is at the abnormal deterioration level and the battery safety diagnosis is at an abnormal deterioration terminal level (or based on the battery durability diagnosis being at the condition-failing deterioration level and the battery safety diagnosis being at a condition failing deterioration terminal level).

According to an embodiment, the processor may determine the final diagnosis level of the battery status as a first level to output a notification for condition-satisfying battery use based on the battery durability diagnosis and the battery safety diagnosis being at a condition-satisfying deterioration level, determine the final diagnosis level of the battery status as a second level to output a notification for battery diagnosis reservation based on the battery durability diagnosis being at a condition-failing deterioration level and the battery safety diagnosis being at the condition-satisfying deterioration level or a condition-failing deterioration initial level, determine the final diagnosis level of the battery status as a third level to output a notification for battery immediate diagnosis based on the battery durability diagnosis being at the condition-failing deterioration level and the battery safety diagnosis being at a condition-failing deterioration mid-term level, and determine the final diagnosis level of the battery status as a fourth level to output a notification for battery immediate replacement based on the battery durability diagnosis being at the condition-failing deterioration level and the battery safety diagnosis being at a condition failing deterioration terminal level.

According to an aspect of the present disclosure, a battery diagnosis method includes obtaining data of a battery to be diagnosed, checking a distribution of State of Health (SOH) parameters and an inter-cell voltage deviation from the data, performing a battery durability diagnosis based on a first diagnosis criterion index, obtaining data corresponding to a plurality of preset safety diagnostic items from the battery to be diagnosed, performing the battery safety diagnosis based on a second diagnosis criterion index, and determining a final diagnosis level of the battery status based on the battery durability diagnosis and the battery safety diagnosis.

### BRIEF DESCRIPTION OF THE DRAWINGS

The above and other objects, features and advantages of the present disclosure should be more apparent from the following detailed description taken in conjunction with the accompanying drawings:

FIG. 1 is a diagram for describing a battery diagnosis apparatus for diagnosing a battery of a vehicle, according to an embodiment of the present disclosure;

FIG. 2 is a block diagram illustrating a configuration of a battery diagnosis apparatus, according to an embodiment of the present disclosure;

FIG. 3 is a graph illustrating an average SOH percentile range by vehicle mileage for a battery durability diagnosis, according to an embodiment of the present disclosure;

FIG. 4 is a diagram illustrating a first diagnosis criterion index for a battery durability diagnosis, according to an embodiment of the present disclosure;

FIG. 5 is a diagram illustrating a second diagnosis criterion index for a battery safety diagnosis, according to an embodiment of the present disclosure;

FIG. 6 is a diagram illustrating a criterion index for determining a final diagnosis level of a battery status, according to an embodiment of the present disclosure;

FIG. 7 is a diagram illustrating a notification output corresponding to a final diagnosis level of a battery status, according to an embodiment of the present disclosure;

FIGS. 8 to 11 are flowcharts for describing a battery diagnosis method, according to an embodiment of the present disclosure; and

FIG. 12 illustrates a computing system in a vehicle, according to an embodiment of the present disclosure.

### DETAILED DESCRIPTION

Hereinafter, some embodiments of the present disclosure are described in detail with reference to the accompanying drawings. In the drawings, the same reference numerals are used throughout to designate the same or equivalent elements. Further, in describing the embodiment of the present disclosure, a detailed description of the related known configuration or function has been omitted when it is determined that it interferes with the understanding of the embodiment of the present disclosure.

In describing the components of the embodiment according to the present disclosure, terms such as first, second, A, B, (a), (b), and the like may be used. These terms are merely intended to distinguish the components from other components, and the terms do not limit the nature, order or sequence of the components. Unless otherwise defined, all terms including technical and scientific terms used herein have the same meaning as commonly understood by one of ordinary skill in the art to which this disclosure belongs. It should be further understood that terms, such as those defined in commonly used dictionaries, should be interpreted as having a meaning that is consistent with their meaning in the context of the relevant art and should not be interpreted in an idealized or overly formal sense unless expressly so defined herein.

In describing the components of the embodiment according to the present disclosure, the term “normal” may refer to satisfying related and/or corresponding condition(s) that may be predetermined, and the term “abnormal” may refer to failing to satisfy related and/or corresponding condition(s) that may be predetermined. For example, when a predetermined condition corresponding to a related and/or corresponding diagnostic feature is not satisfied, the related diagnostic feature may be determined to be abnormal or at an abnormal level. In addition, when a predetermined condition corresponding to a related and/or corresponding diagnostic feature is satisfied, the related diagnostic feature may be determined to be normal or at a normal level.

When a component, controller, device, element, apparatus, or the like of the present disclosure is described as having a purpose or performing an operation, function, or the like, the component, controller, device, element, apparatus, or the like should be considered herein as being “configured to” meet that purpose or to perform that operation or function. Each component, controller, device, element, apparatus, and the like may separately embody or be included with a processor and a memory, such as a non-transitory computer readable media, as part of the apparatus.

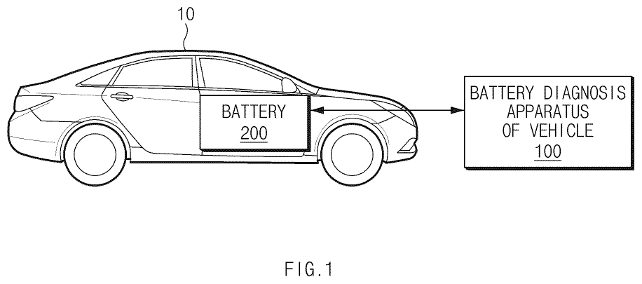

Hereinafter, embodiments of the present disclosure are described in detail with reference to FIGS. 1-12 .

FIG. 1 is a diagram for describing a battery diagnosis apparatus for diagnosing a battery of a vehicle, according to an embodiment of the present disclosure.

As illustrated in FIG. 1, a battery diagnosis apparatus 100 of the present disclosure may diagnose the battery status based on a first diagnosis criterion index for diagnosing the durability of a battery 200 in a vehicle 10 and a second diagnosis criterion index for diagnosing the safety of the battery 200.

In this case, the battery diagnosis apparatus 100 may be integrally mounted inside the vehicle 10 or may be separately placed outside the vehicle 10.

The battery diagnosis apparatus 100 may obtain data of the battery to be diagnosed, may check a distribution of State of Health (SOH) parameters and an inter-cell voltage deviation from the data, may perform a battery durability diagnosis based on the first diagnosis criterion index, may obtain data corresponding to a plurality of preset safety diagnostic items from the battery to be diagnosed, may perform a battery safety diagnosis based on the second diagnosis criterion index, and may determine the final diagnosis level of the battery status based on the battery durability diagnosis and the battery safety diagnosis.

In this case, the battery diagnosis apparatus 100 may obtain cloud data including vehicle mileage-specific SOH (State Of Health) data of the battery to be diagnosed when a diagnosis request for the battery is received when data of the battery to be diagnosed is obtained.

In addition, when the battery durability diagnosis is performed, the battery diagnosis apparatus 100 may first determine whether the vehicle mileage-specific SOH data of the battery to be diagnosed is distributed within an average SOH percentile range by vehicle mileage, and when the vehicle mileage-specific SOH data is not distributed within the average SOH percentile range by the vehicle mileage, may secondarily determine whether the inter-cell voltage deviation of the battery to be diagnosed is abnormal based on the first diagnosis criterion index, and may calculate the battery durability level based on the results of the first and second determinations to perform the battery durability diagnosis based on the calculated battery durability level.

In this case, when the first determination is performed, the battery diagnosis apparatus 100 may diagnose the battery durability level as a normal deterioration level when the vehicle mileage-specific SOH data is distributed within the average SOH percentile range by the vehicle mileage.

In addition, when the second determination is performed, the battery diagnosis apparatus 100 may diagnose the battery durability level as an abnormal deterioration level based on the first diagnosis criterion index including a plurality of preset abnormal deterioration criterion indices when the vehicle mileage-specific SOH data is not distributed within the average SOH percentile range by the vehicle mileage.

For example, the battery diagnosis apparatus 100 may determine whether the inter-cell voltage deviation of the battery to be diagnosed is abnormal when the abnormal deterioration level is diagnosed, may diagnose the battery durability level as an abnormal deterioration initial level when the inter-cell voltage deviation is normal when the vehicle mileage-specific SOH data is not distributed within the average SOH percentile range by the vehicle mileage, may determine whether the inter-cell voltage deviation is included in a first abnormal deterioration criterion index among the plurality of abnormal deterioration criterion indices when the inter-cell voltage deviation is abnormal, may diagnose the battery durability level as an abnormal deterioration mid-term level when the inter-cell voltage deviation is included in the first abnormal deterioration criterion index, may determine whether the inter-cell voltage deviation is included in a second abnormal deterioration criterion index among the plurality of abnormal deterioration criterion indices when the inter-cell voltage deviation is not included in the first abnormal deterioration criterion index, and may diagnose the battery durability level as abnormal deterioration terminal level when the inter-cell voltage deviation is included in the second abnormal deterioration criterion index.

In addition, the battery diagnosis apparatus 100 may check a BMS (Battery Management System) estimated SOH value when calculating the battery durability level, and may calculate the battery durability level through a formula consisting of L=100*(SOH−70)/30 (where, L is the battery durability level, and is based on BOL (Beginning Of Life) 100% to EOL (End Of Life) 70%).

Next, the battery diagnosis apparatus 100 may obtain data corresponding to a plurality of preset safety diagnostic items when performing a battery safety diagnosis, may determine whether the obtained data satisfies the diagnostic conditions for the plurality of safety diagnostic items based on the second diagnosis criterion index, may determine the battery safety level based on the diagnostic items that do not satisfy the diagnostic conditions, and may perform the battery safety diagnosis based on the determined battery safety level.

In this case, the battery diagnosis apparatus 100 may determine whether a first diagnostic condition for an over-temperature diagnostic item, an over-voltage diagnostic item, and a low-voltage diagnostic item among the plurality of safety diagnostic items is satisfied when the battery safety level is determined, may first determine the battery safety level based on the number of diagnostic items that are not satisfied with the first diagnostic condition, may determine whether a second diagnostic condition for a cell voltage change item during charging is satisfied and a third diagnostic condition for the inter-cell voltage deviation item during charging is satisfied when all of the first diagnostic conditions are satisfied, and may secondly determine the battery safety level based on the diagnostic items that are not satisfied with the second and third diagnostic conditions.

In addition, the battery diagnosis apparatus 100 may determine the final diagnosis level of the battery status as a first level to output a notification for normal battery use when the final diagnosis level of the battery status is determined and when both the battery durability diagnosis and the battery safety diagnosis are at a normal deterioration level, may determine the final diagnosis level of the battery status as a second level to output a notification for battery diagnosis reservation when the battery durability diagnosis is at an abnormal deterioration level and the battery safety diagnosis is at the normal deterioration level or an abnormal deterioration initial level, may determine the final diagnosis level of the battery status as a third level to output a notification for battery immediate diagnosis when the battery durability diagnosis is at the abnormal deterioration level and the battery safety diagnosis is at an abnormal deterioration mid-term level, and may determine the final diagnosis level of the battery status as a fourth level to output a notification for battery immediate replacement when the battery durability diagnosis is at the abnormal deterioration level and the battery safety diagnosis is at an abnormal deterioration terminal level.

As in the above description, the present disclosure may diagnose the battery status based on the first diagnosis criterion index set for battery durability diagnosis and the second diagnosis criterion index set for battery safety diagnosis, thereby setting a wide diagnosis criterion range while setting a response strategy for each diagnosis section, and thereby enabling flexible customer response and reducing quality costs due to overdiagnosis.

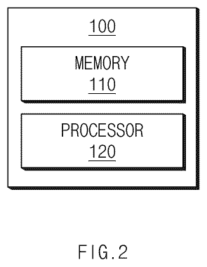

FIG. 2 is a block diagram illustrating a configuration of a battery diagnosis apparatus, according to an embodiment of the present disclosure.

As illustrated in FIG. 2, the battery diagnosis apparatus 100 according to the present disclosure may include a memory 110 storing a first diagnosis criterion index set for a battery durability diagnosis and a second diagnosis criterion index set for a battery safety diagnosis, and a processor 120 diagnosing a battery status based on the first diagnosis criterion index and the second diagnosis criterion index.

The processor 120 may obtain data of the battery to be diagnosed, may check a distribution of SOH parameters and an inter-cell voltage deviation from the data, may perform a battery durability diagnosis based on the first diagnosis criterion index, may obtain data corresponding to a plurality of preset safety diagnostic items from the battery to be diagnosed, may perform a battery safety diagnosis based on the second diagnosis criterion index, and may determine the final diagnosis level of the battery status based on the battery durability diagnosis and the battery safety diagnosis.

In this case, when data of the battery to be diagnosed is obtained, the processor 120 may obtain cloud data including vehicle mileage-specific SOH (State Of Health) data of the battery to be diagnosed when receiving a battery diagnosis request.

In addition, when the battery durability diagnosis is performed, the processor 120 may first determine whether the vehicle mileage-specific SOH data of the battery to be diagnosed is distributed within an average SOH percentile range by vehicle mileage, may secondarily determine whether the inter-cell voltage deviation of the battery to be diagnosed is abnormal based on the first diagnosis criterion index when the vehicle mileage-specific SOH data is not distributed within the average SOH percentile range by the vehicle mileage, and may calculate the battery durability level based on the results of the first and second determinations to perform the battery durability diagnosis based on the calculated battery durability level.

In this case, when the first determination is performed, the processor 120 may diagnose the battery durability level as a normal deterioration level when the vehicle mileage-specific SOH data is distributed within the average SOH percentile range by the vehicle mileage.

In addition, when the second determination is performed, the processor 120 may diagnose the battery durability level as an abnormal deterioration level based on the first diagnosis criterion index including a plurality of preset abnormal deterioration criterion indices when the vehicle mileage-specific SOH data is not distributed within the average SOH percentile range by the vehicle mileage.

In detail, the processor 120 may determine whether the inter-cell voltage deviation of the battery to be diagnosed is abnormal when the abnormal deterioration level is diagnosed, may diagnose the battery durability level as an abnormal deterioration initial level when the inter-cell voltage deviation is normal when the vehicle mileage-specific SOH data is not distributed within the average SOH percentile range by the vehicle mileage, may determine whether the inter-cell voltage deviation is included in a first abnormal deterioration criterion index among the plurality of abnormal deterioration criterion indices when the inter-cell voltage deviation is abnormal, may diagnose the battery durability level as an abnormal deterioration mid-term level when the inter-cell voltage deviation is included in the first abnormal deterioration criterion index, may determine whether the inter-cell voltage deviation is included in a second abnormal deterioration criterion index among the plurality of abnormal deterioration criterion indices when the inter-cell voltage deviation is not included in the first abnormal deterioration criterion index, and may diagnose the battery durability level as abnormal deterioration terminal level when the inter-cell voltage deviation is included in the second abnormal deterioration criterion index.

As an example, a first abnormal deterioration criterion index may include a first cell deviation criterion voltage per mileage section, and a second abnormal deterioration criterion index may include a second cell deviation criterion voltage that is greater than the first cell deviation criterion voltage per mileage section. The processor 120 may diagnose the battery durability level as an abnormal deterioration mid-term level when a condition that the inter-cell voltage deviation is equal to or greater than the first cell deviation criterion voltage in a specific mileage section is satisfied, and may diagnose the battery durability level as an abnormal deterioration terminal level when a condition that the inter-cell voltage deviation is equal to or greater than the second cell deviation criterion voltage in a specific mileage section is satisfied.

For example, the processor 120 may diagnose the battery durability level as an abnormal deterioration mid-term level when any one of the following conditions is satisfied: a first condition in which the inter-cell voltage deviation is 60 mV or more in a section of 0 to less than 50,000 km, a second condition in which the inter-cell voltage deviation is 90 mV or more in a section of 50,000 km to less than 100,000 km, a third condition in which the inter-cell voltage deviation is 120 mV or more in a section of 100,000 km to less than 200,000 km, and a fourth condition in which the inter-cell voltage deviation is 200 mV or more in a section of 200,000 km to less than 300,000 km.

In this case, the first to fourth conditions may further include a condition in which the SOC (State Of Charge) of the battery is about 20% or more and the temperature is about 25 degrees or more.

For example, the processor 120 may diagnose the battery durability level as an abnormal deterioration terminal level when any one of the following conditions is satisfied: a fifth condition in which the inter-cell voltage deviation is 90 mV or more in a section of 0 to less than 50,000 km, a sixth condition in which the inter-cell voltage deviation is 120 mV or more in a section of 50,000 km to less than 100,000 km, a seventh condition in which the inter-cell voltage deviation is 150 mV or more in a section of 100,000 km to less than 200,000 km, and an eighth condition in which the inter-cell voltage deviation is 250 mV or more in a section of 200,000 km to less than 300,000 km.

In this case, the fifth to eighth conditions may further include a condition in which the SOC (State Of Charge) of the battery is about 20% or more and the temperature is about 25 degrees or more.

Next, the processor 120 may check the BMS (Battery Management System) estimated SOH value when calculating the battery durability level, and may calculate the battery durability level through a formula consisting of L=100*(SOH−70)/30 (where L is the battery durability level and is based on BOL (Beginning Of Life) 100% to EOL (End Of Life) 70%).

Next, the processor 120 may obtain data corresponding to a plurality of preset safety diagnostic items when performing a battery safety diagnosis, may determine whether the obtained data satisfies the diagnostic conditions for the plurality of safety diagnostic items based on the second diagnosis criterion index, may determine the battery safety level based on the diagnostic items that do not satisfy the diagnostic conditions, and may perform the battery safety diagnosis based on the determined battery safety level.

In this case, the processor 120 may determine whether a first diagnostic condition for an over-temperature diagnostic item, an over-voltage diagnostic item, and a low-voltage diagnostic item among the plurality of safety diagnostic items is satisfied when the battery safety level is determined, may first determine the battery safety level based on the number of diagnostic items that are not satisfied with the first diagnostic condition, may determine whether a second diagnostic condition for a cell voltage change item during charging is satisfied and a third diagnostic condition for the inter-cell voltage deviation item during charging is satisfied when all of the first diagnostic conditions are satisfied, and may secondly determine the battery safety level based on the diagnostic items that are not satisfied with the second and third diagnostic conditions.

As an example, when determining whether the first diagnostic condition is satisfied, the processor 120 may determine whether the first diagnostic condition is satisfied for the overtemperature diagnostic item having the diagnostic condition that a maximum temperature Tmax is less than about 60 degrees, the overvoltage diagnostic item having the diagnostic condition that a maximum voltage Vmax is less than about 4.2 V, and the low voltage diagnostic item having the diagnostic condition that a minimum voltage Vmin is more than about 2.0 V.

In addition, when the battery safety level is first determined, the processor 120 may determine the battery safety level as an abnormal deterioration mid-term level when the number of diagnostic items that do not satisfy the first diagnostic condition is “1”, and may determine the battery safety level as an abnormal deterioration terminal level when the number of diagnostic items that do not satisfy the first diagnostic condition is more than “1”.

As an example, when the maximum temperature Tmax is maintained at about 60 degrees or more for about 1 second or more, the processor 120 may recognize the diagnostic condition of the overtemperature diagnostic item as unsatisfactory, when the maximum voltage Vmax is maintained at about 4.3 V or more for about 1 second, the processor 120 may recognize the diagnostic condition of the overvoltage diagnostic item as unsatisfactory, and when the minimum voltage Vmin is maintained at about 2.0 V for about 1 second, the processor 120 may recognize the diagnostic condition of the low voltage diagnostic item as unsatisfactory.

In addition, when determining whether the second and third diagnostic conditions are satisfied, the processor 120 may determine whether the second diagnostic condition for the cell voltage change item during charging among the plurality of safety diagnostic items is satisfied when all of the first diagnostic conditions are satisfied, and may determine whether the vehicle mileage is checked when the second diagnostic condition is satisfied, and may determine whether the third diagnostic condition for the inter-cell voltage deviation item during charging corresponding to the checked vehicle mileage is satisfied.

In this case, when determining whether the second diagnostic condition is satisfied, the processor 120 may determine whether the second diagnostic condition for the cell voltage change item during charging is satisfied, which has a diagnostic condition that the individual cell voltage is less than about 250 mV during rapid charging or the individual cell voltage is less than about 100 mV during slow charging.

In addition, when the battery safety level is secondly determined, the processor 120 may determine the battery safety level as an abnormal deterioration initial level when the second diagnostic condition is not satisfied.

Next, when determining whether the third diagnostic condition is satisfied, the processor 120 may determine whether the condition that the cell voltage deviation during charging corresponding to the determined vehicle mileage is less than a first cell deviation reference voltage is satisfied, and when the condition that the cell voltage deviation during charging corresponding to the determined vehicle mileage is less than the first cell deviation reference voltage is not satisfied, the processor 120 may determine whether the condition that the cell voltage deviation during charging corresponding to the determined vehicle mileage is less than a second cell deviation reference voltage is satisfied.

For example, when determining whether the condition of being less than the first cell deviation reference voltage is satisfied, the processor 120 may determine that the condition of being less than the first cell deviation reference voltage is satisfied when any one of the following is satisfied: a first condition in which the inter-cell voltage deviation corresponding to the vehicle mileage is less than 60 mV in a section of 0 to less than 50,000 km, a second condition in which the inter-cell voltage deviation is less than 90 mV in a section of 50,000 km to less than 100,000 km, a third condition in which the inter-cell voltage deviation is less than 120 mV in a section of 100,000 km to less than 200,000 km, and a fourth condition in which the inter-cell voltage deviation is less than 200 mV in a section of 200,000 km to less than 300,000 km.

In addition, when determining whether the condition of being less than the second cell deviation reference voltage is satisfied, the processor 120 may determine that the condition of being less than the second cell deviation reference voltage is satisfied when any one of the following is satisfied: a fifth condition in which the inter-cell voltage deviation corresponding to the vehicle mileage is less than 90 mV in the section of 0 to less than 50,000 km, a sixth condition in which the inter-cell voltage deviation is less than 120 mV in the section of 50,000 km to less than 100,000 km, a seventh condition in which the inter-cell voltage deviation is less than 150 mV in the section of 100,000 km to less than 200,000 km, and an eighth condition in which the inter-cell voltage deviation is less than 250 mV in the section of 200,000 km to less than 300,000 km.

Next, when secondly determining the battery safety level, the processor 120 may determine the battery safety level as a normal deterioration level when the condition of being less than the first cell deviation reference voltage among the third diagnostic conditions is satisfied, may determine the battery safety level as an abnormal deterioration mid-term level when the condition of being less than the second cell deviation reference voltage among the third diagnostic conditions is satisfied, and may determine the battery safety level as an abnormal deterioration terminal level when the condition of being less than the second cell deviation reference voltage among the third diagnostic conditions is not satisfied.

In addition, the processor 120 may determine the final diagnosis level of the battery status as a first level to output a notification for normal battery use when the final diagnosis level of the battery status is determined and when both the battery durability diagnosis and the battery safety diagnosis are at a normal deterioration level, may determine the final diagnosis level of the battery status as a second level to output a notification for battery diagnosis reservation when the battery durability diagnosis is at an abnormal deterioration level and the battery safety diagnosis is at the normal deterioration level or an abnormal deterioration initial level, may determine the final diagnosis level of the battery status as a third level to output a notification for battery immediate diagnosis when the battery durability diagnosis is at the abnormal deterioration level and the battery safety diagnosis is at an abnormal deterioration mid-term level, and may determine the final diagnosis level of the battery status as a fourth level to output a notification for battery immediate replacement when the battery durability diagnosis is at the abnormal deterioration level and the battery safety diagnosis is at an abnormal deterioration terminal level.

In this case, the processor 120, when the final diagnosis level of the battery status is at the second level, may output a notification for battery diagnosis reservation and may track and manage the cloud data of the battery to be diagnosed.

In addition, the processor 120 may output a notification for immediate battery diagnosis and request vehicle center entry and maintenance when the final diagnosis level of the battery status is at the third level.

In addition, the processor 120 may output a notification for immediate battery replacement and may request emergency dispatch from the fire department when the final diagnosis level of the battery status is at the fourth level.

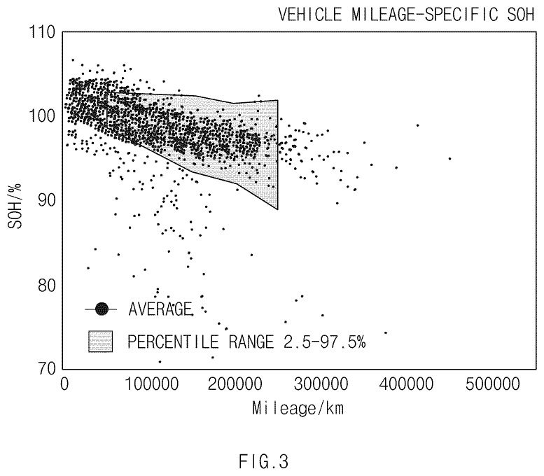

FIG. 3 is a graph illustrating an average SOH percentile range by vehicle mileage for a battery durability diagnosis, according to an embodiment of the present disclosure.

As illustrated in FIG. 3, the present disclosure may obtain cloud data including SOH (State Of Health) data by vehicle mileage of the battery to be diagnosed when a battery diagnosis request is received.

In addition, the present disclosure may first determine whether the vehicle mileage-specific SOH data of the battery to be diagnosed is distributed within the average SOH percentile range by vehicle mileage, and when the vehicle mileage-specific SOH data is not distributed within the average SOH percentile range by the vehicle mileage, the present disclosure may secondly determine whether the inter-cell voltage deviation of the battery to be diagnosed is abnormal based on the first diagnosis criterion index, may calculate the battery durability level based on the results of the first and second determinations, and may perform battery durability diagnosis based on the calculated battery durability level.

In this case, the present disclosure may diagnose the battery durability level as a normal deterioration level when the vehicle mileage-specific SOH data is distributed within the average SOH percentile range by the vehicle mileage.

In addition, the present disclosure may diagnose the battery durability level as an abnormal deterioration level based on a first diagnosis criterion index including a plurality of preset abnormal deterioration criterion indices when the vehicle mileage-specific SOH data is not distributed within the average SOH percentile range by the vehicle mileage.

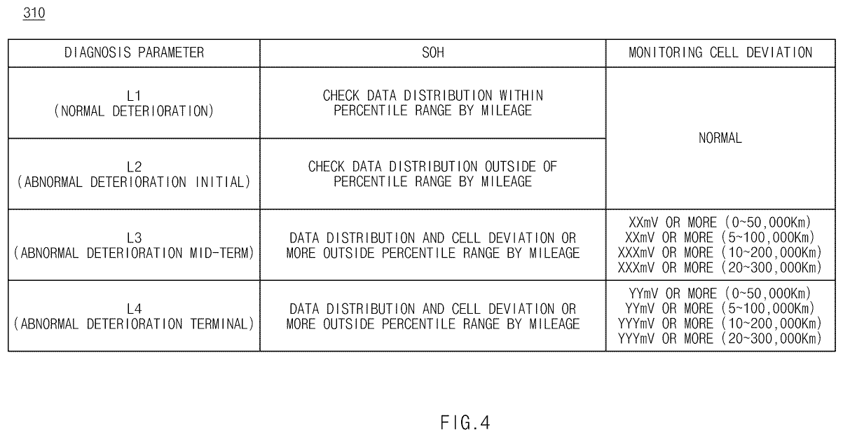

FIG. 4 is a diagram illustrating a first diagnosis criterion index for a battery durability diagnosis, according to an embodiment of the present disclosure.

As illustrated in FIG. 4, the present disclosure may diagnose the battery durability level as a normal deterioration level L1 when the vehicle mileage-specific SOH data is distributed within the vehicle mileage-specific average SOH percentile range.

In addition, the present disclosure may diagnose the battery durability level as an abnormal deterioration level based on a first diagnosis criterion index 310 including a plurality of preset abnormal deterioration criterion indices when the vehicle mileage-specific SOH data is not distributed within the average SOH percentile range by the vehicle mileage.

For example, the present disclosure may determine whether the inter-cell voltage deviation of the battery to be diagnosed is abnormal when the vehicle mileage-specific SOH data is not distributed within the vehicle mileage-specific average SOH percentile range, and may diagnose the battery durability level as an abnormal deterioration initial level L2 when the inter-cell voltage deviation is normal.

Next, the present disclosure may determine whether the inter-cell voltage deviation is included in a first abnormal deterioration criterion index among a plurality of abnormal deterioration criterion indices when the inter-cell voltage deviation is abnormal, and may diagnose the battery durability level as an abnormal deterioration mid-term level L3 when the inter-cell voltage deviation is included in the first abnormal deterioration criterion index.

In addition, the present disclosure may determine whether the inter-cell voltage deviation is included in a second abnormal deterioration criterion index among the plurality of abnormal deterioration criterion indices when the inter-cell voltage deviation is not included in the first abnormal deterioration criterion index, and may diagnose the battery durability level as an abnormal deterioration terminal level L4 when the inter-cell voltage deviation is included in the second abnormal deterioration criterion index.

When the first abnormal deterioration criterion index includes the first cell deviation criterion voltage per mileage section, and the second abnormal deterioration criterion index includes the second cell deviation criterion voltage that is greater than the first cell deviation criterion voltage per mileage section, the present disclosure may diagnose the battery durability level as the abnormal deterioration mid-term level L3 when the condition that the inter-cell voltage deviation is equal to or greater than the first cell deviation criterion voltage in a specific mileage section is satisfied, and may diagnose the battery durability level as the abnormal deterioration terminal level L4 when the condition that the inter-cell voltage deviation is equal to or greater than the second cell deviation criterion voltage in a specific mileage section is satisfied.

For example, the present disclosure may diagnose the battery durability level as the abnormal deterioration mid-term level L3 when any one of the following conditions is satisfied: a first condition in which the inter-cell voltage deviation is about 60 mV or more in a section of 0 to less than 50,000 km, a second condition in which the inter-cell voltage deviation is about 90 mV or more in a section of 50,000 km to less than 100,000 km, a third condition in which the inter-cell voltage deviation is about 120 mV or more in a section of 100,000 km to less than 200,000 km, and a fourth condition in which the inter-cell voltage deviation is about 200 mV or more in a section of 200,000 km to less than 300,000 km.

In this case, the first to fourth conditions may further include a condition in which the SOC (State Of Charge) of the battery is about 20% or more and the temperature is about 25 degrees or more.

In addition, the present disclosure may diagnose the battery durability level as the abnormal deterioration terminal level L4 when any one of the following conditions is satisfied: a fifth condition in which the inter-cell voltage deviation is about 90 mV or more in a section of 0 to less than 50,000 km, a sixth condition in which the inter-cell voltage deviation is about 120 mV or more in a section of 50,000 km to less than 100,000 km, a seventh condition in which the inter-cell voltage deviation is about 150 mV or more in a section of 100,000 km to less than 200,000 km, and an eighth condition in which the inter-cell voltage deviation is about 250 mV or more in a section of 200,000 km to less than 300,000 km.

In this case, the fifth to eighth conditions may further include a condition in which the SOC (State Of Charge) of the battery is about 20% or more and the temperature is about 25 degrees or more.

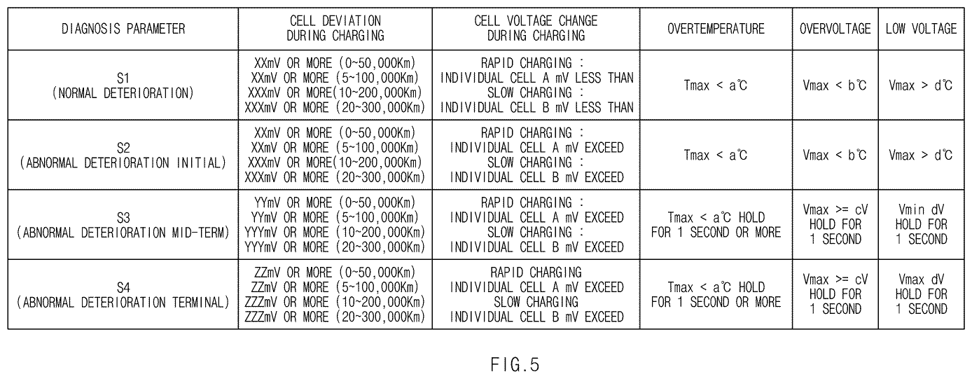

FIG. 5 is a diagram illustrating a second diagnosis criterion index for a battery safety diagnosis, according to an embodiment of the present disclosure.

As illustrated in FIG. 5, the present disclosure may obtain data corresponding to a plurality of preset safety diagnostic items, may determine whether the obtained data satisfies diagnostic conditions for the plurality of safety diagnostic items based on a second diagnosis criterion index 320, may determine a battery safety level based on a diagnostic item that does not satisfy the diagnostic condition, and may perform a battery safety diagnosis based on the determined battery safety level.

In this case, the present disclosure may determine whether a first diagnostic condition for an over-temperature diagnostic item, an over-voltage diagnostic item, and a low-voltage diagnostic item among the plurality of safety diagnostic items is satisfied, may first determine the battery safety level based on the number of diagnostic items that are not satisfied with the first diagnostic condition, may determine whether a second diagnostic condition for a cell voltage change item during charging is satisfied and a third diagnostic condition for the inter-cell voltage deviation item during charging is satisfied, when all of the first diagnostic conditions are satisfied, and may secondly determine the battery safety level based on the diagnostic items that are not satisfied with the second and third diagnostic conditions.

As an example, when determining whether the first diagnostic condition is satisfied, the present disclosure may determine whether the first diagnostic condition is satisfied for the overtemperature diagnostic item having the diagnostic condition that a maximum temperature Tmax is less than about 60 degrees, the overvoltage diagnostic item having the diagnostic condition that a maximum voltage Vmax is less than about 4.2 V, and the low voltage diagnostic item having the diagnostic condition that a minimum voltage Vmin is more than about 2.0 V.

In addition, when the battery safety level is first determined, the present disclosure may determine the battery safety level as an abnormal deterioration mid-term level S3 when the number of diagnostic items that do not satisfy the first diagnostic condition is “1”, and may determine the battery safety level as an abnormal deterioration terminal level S4 when the number of diagnostic items that do not satisfy the first diagnostic condition is more than “1”.

As an example, when the maximum temperature Tmax is maintained at about 60 degrees or more for about 1 second or more, the present disclosure may recognize the diagnostic condition of the overtemperature diagnostic item as unsatisfactory, when the maximum voltage Vmax is maintained at about 4.3 V or more for about 1 second, the present disclosure may recognize the diagnostic condition of the overvoltage diagnostic item as unsatisfactory, and when the minimum voltage Vmin is maintained at about 2.0 V for about 1 second, the present disclosure may recognize the diagnostic condition of the low voltage diagnostic item as unsatisfactory.

In addition, when determining whether the second and third diagnostic conditions are satisfied, the present disclosure may determine whether the second diagnostic condition for the cell voltage change item during charging among the plurality of safety diagnostic items is satisfied when all of the first diagnostic conditions are satisfied, and may determine whether the vehicle mileage is checked when the second diagnostic condition is satisfied, and may determine whether the third diagnostic condition for the inter-cell voltage deviation item during charging corresponding to the checked vehicle mileage is satisfied.

In this case, when determining whether the second diagnostic condition is satisfied, the present disclosure may determine whether the second diagnostic condition for the cell voltage change item during charging is satisfied, which has a diagnostic condition that the individual cell voltage is less than about 250 mV during rapid charging or the individual cell voltage is less than about 100 mV during slow charging.

In addition, when the battery safety level is secondly determined, the present disclosure may determine the battery safety level as an abnormal deterioration initial level S2 when the second diagnostic condition is not satisfied.

Next, when determining whether the third diagnostic condition is satisfied, the present disclosure may determine whether the condition that the cell voltage deviation during charging corresponding to the determined vehicle mileage is less than a first cell deviation reference voltage is satisfied, and when the condition that the cell voltage deviation during charging corresponding to the determined vehicle mileage is less than the first cell deviation reference voltage is not satisfied, the present disclosure may determine whether the condition that the cell voltage deviation during charging corresponding to the determined vehicle mileage is less than a second cell deviation reference voltage is satisfied.

For example, when determining whether the condition of being less than the first cell deviation reference voltage is satisfied, the present disclosure may determine that the condition of being less than the first cell deviation reference voltage is satisfied when any one of the following is satisfied: a first condition in which the inter-cell voltage deviation corresponding to the vehicle mileage is less than 60 mV in a section of 0 to less than 50,000 km, a second condition in which the inter-cell voltage deviation is less than 90 mV in a section of 50,000 km to less than 100,000 km, a third condition in which the inter-cell voltage deviation is less than 120 mV in a section of 100,000 km to less than 200,000 km, and a fourth condition in which the inter-cell voltage deviation is less than 200 mV in a section of 200,000 km to less than 300,000 km.

For example, when determining whether the condition of being less than the second cell deviation reference voltage is satisfied, the present disclosure may determine that the condition of being less than the second cell deviation reference voltage is satisfied when any one of the following is satisfied: a fifth condition in which the inter-cell voltage deviation corresponding to the vehicle mileage is less than 90 mV in a section of 0 to less than 50,000 km, a sixth condition in which the inter-cell voltage deviation is less than 120 mV in a section of 50,000 km to less than 100,000 km, a seventh condition in which the inter-cell voltage deviation is less than 150 mV in a section of 100,000 km to less than 200,000 km, and an eighth condition in which the inter-cell voltage deviation is less than 250 mV in a section of 200,000 km to less than 300,000 km.

Next, when the battery safety level is secondly determined, the present disclosure may determine the battery safety level as a normal deterioration level S1 when the condition of being less than a first cell deviation reference voltage among the third diagnostic conditions is satisfied, may determine the battery safety level as the abnormal deterioration mid-term level S3 when the condition of being less than a second cell deviation reference voltage among the third diagnostic conditions is satisfied, and may determine the battery safety level as the abnormal deterioration terminal level S4 when the condition of being less than the second cell deviation reference voltage among the third diagnostic conditions is not satisfied.

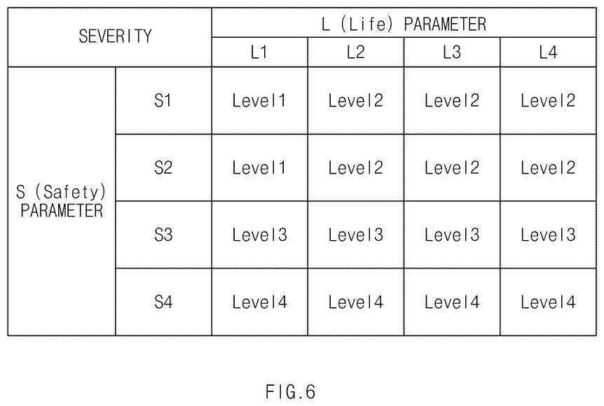

FIG. 6 is a diagram illustrating a criterion index for determining a final diagnosis level of a battery status, according to an embodiment of the present disclosure.

As illustrated in FIG. 6, the present disclosure may determine the final diagnosis level of the battery status based on the battery durability diagnosis and the battery safety diagnosis.

When both the battery durability diagnosis and the battery safety diagnosis are the normal deterioration levels L1 and S1, the present disclosure may determine the final diagnosis level of the battery status as a first level (LEVEL 1) to output a notification for normal battery use.

In addition, the present disclosure may determine the final diagnosis level of the battery status as a second level (LEVEL 2) to output a notification for battery diagnosis reservation when the battery durability diagnosis is one of the abnormal deterioration levels L2, L3, and L4 and the battery safety diagnosis is the normal deterioration level S1 or the abnormal deterioration initial level S2.

In addition, the present disclosure may determine the final diagnosis level of the battery status as a third level (LEVEL 3) when the battery durability diagnosis is the normal deterioration level L1 or any one of the abnormal deterioration levels L2, L3, and L4 and the battery safety diagnosis is the abnormal deterioration mid-term level S3, and may output a notification for immediate battery diagnosis.

In addition, the present disclosure may determine the final diagnosis level of the battery status as a fourth level (LEVEL 4) when the battery durability diagnosis is the normal deterioration level L1 or any one of the abnormal deterioration levels L2, L3, and L4 and the battery safety diagnosis is the abnormal deterioration terminal level S4, and may output a notification for immediate replacement of the battery.

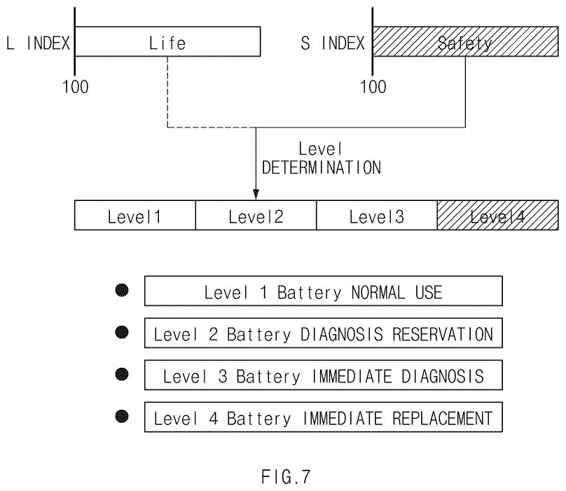

FIG. 7 is a diagram illustrating a notification output corresponding to a final diagnosis level of a battery status, according to an embodiment of the present disclosure.

As illustrated in FIG. 7, the present disclosure may determine the final diagnosis level of the battery status based on the battery durability diagnosis and the battery safety diagnosis.

In this case, the present disclosure may determine the final diagnosis level of the battery status as the first level (LEVEL 1) when both the battery durability diagnosis and the battery safety diagnosis are normal deterioration levels, and may output a notification for normal battery use.

In addition, the present disclosure may output a notification for a battery diagnosis reservation when the final diagnosis level of the battery status is the second level, and may track and manage the cloud data of the battery to be diagnosed.

In addition, the present disclosure may output a notification for an immediate battery diagnosis when the final diagnosis level of the battery status is the third level, and may request a vehicle center entry and maintenance.

In addition, the present disclosure may output a notification for an immediate battery replacement when the final diagnosis level of the battery status is the fourth level, and may request an emergency dispatch from the fire department.

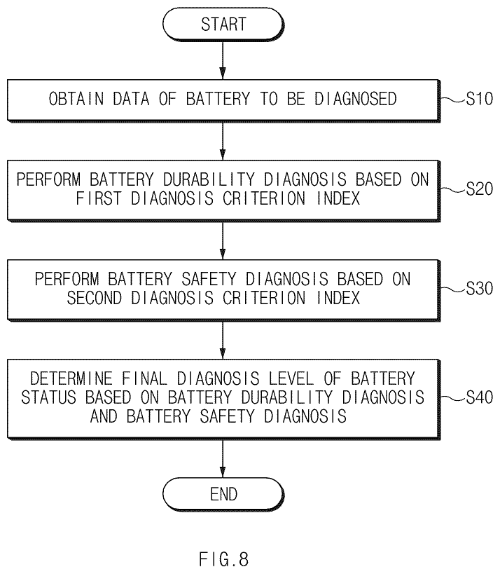

FIGS. 8-11 are flowcharts for describing a battery diagnosis method, according to an embodiment of the present disclosure.

As illustrated in FIG. 8, the present disclosure may obtain data of a battery to be diagnosed (S10).

In this case, the present disclosure may obtain the cloud data including the SOH (State Of Health) data by vehicle mileage of the battery to be diagnosed when a request for battery diagnosis is received.

In addition, the present disclosure may determine the distribution of SOH parameters and inter-cell voltage deviation from the data, and may perform battery durability diagnosis based on a first diagnosis criterion index (S20).

In this case, the present disclosure may first determine whether the vehicle mileage-specific SOH data of the battery to be diagnosed is distributed within the average SOH percentile range by vehicle mileage, and when the vehicle mileage-specific SOH data is not distributed within the average SOH percentile range by the vehicle mileage, the present disclosure may secondly determine whether the inter-cell voltage deviation of the battery to be diagnosed is abnormal based on the first diagnosis criterion index, may calculate the battery durability level based on the results of the first and second determinations, and may perform battery durability diagnosis based on the calculated battery durability level.

Next, the present disclosure may obtain data corresponding to a plurality of preset safety diagnostic items from the battery to be diagnosed, and may perform a battery safety diagnosis based on a second diagnosis criterion index (S30).

In this case, the present disclosure may obtain data corresponding to a plurality of preset safety diagnostic items, may determine whether the obtained data satisfies a diagnostic condition for a plurality of safety diagnostic items based on the second diagnosis criterion index, may determine a battery safety level based on a diagnostic item that does not satisfy the diagnostic condition, and may perform a battery safety diagnosis based on the determined battery safety level.

Next, the present disclosure may determine a final diagnosis level of a battery status based on the battery durability diagnosis and the battery safety diagnosis (S40).

In this case, the present disclosure may determine the final diagnosis level of the battery status as the first level to output a notification for normal battery use when both the battery durability diagnosis and the battery safety diagnosis are at a normal deterioration level, may determine the final diagnosis level of the battery status as the second level to output a notification for a battery diagnosis reservation when the battery durability diagnosis is at an abnormal deterioration level and the battery safety diagnosis is at a normal deterioration level or an abnormal deterioration initial level, may determine the final diagnosis level of the battery status as the third level to output a notification for immediate battery diagnosis when the battery durability diagnosis is at an abnormal deterioration level and the battery safety diagnosis is at an abnormal deterioration mid-term level, and may determine the final diagnosis level of the battery status as the fourth level to output a notification for immediate battery replacement when the battery durability diagnosis is at an abnormal deterioration level and the battery safety diagnosis is at an abnormal deterioration terminal level.

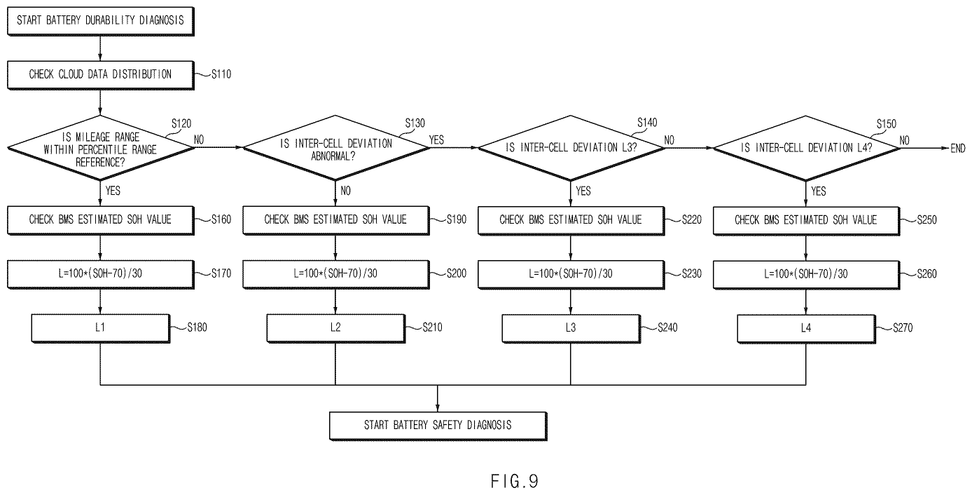

As illustrated in FIG. 9, the battery durability diagnosis method of the present disclosure is described in more detail as follows.

As illustrated in FIG. 9, the present disclosure may obtain the cloud data including the vehicle mileage-specific SOH (State Of Health) data of the battery to be diagnosed when battery durability diagnosis starts, and may check the cloud data distribution (S110).

In addition, the present disclosure may determine whether the vehicle mileage-specific SOH data of the battery to be diagnosed is distributed within the average SOH percentile range by vehicle mileage (S120).

In this case, when the vehicle mileage-specific SOH data of the battery to be diagnosed is distributed within the average SOH percentile range by vehicle mileage (Yes in S120), the present disclosure may check the BMS (Battery Management System) estimated SOH value when the vehicle mileage-specific SOH data is distributed within the vehicle mileage-specific average SOH percentile range (S160), may calculate the battery durability level using the formula consisting of L=100*(SOH−70)/30 (where “L” is the battery durability level, and is based on BOL (Beginning Of Life) 100% to EOL (End Of Life) 70%) (S170), and may diagnose the battery durability level as the normal deterioration level L1 based on the calculation result (S180).

Next, the present disclosure may determine whether the inter-cell voltage deviation of the battery to be diagnosed is abnormal based on the first diagnosis criterion index (S130) when the vehicle mileage-specific SOH data is not distributed within the vehicle mileage-specific average SOH percentile range (No in S120).

In this case, when the inter-cell voltage deviation is normal (No in S130), the present disclosure may check the BMS estimated SOH value (S190), may calculate the battery durability level using the formula consisting of L=100*(SOH−70)/30 (where L is the battery durability level, and is based on BOL (Beginning Of Life) 100% to EOL (End Of Life) 70%) (S200), and may diagnose the battery durability level as the abnormal deterioration initial level L2 based on the calculation result (S210).

Next, the present disclosure may determine whether the inter-cell voltage deviation is included in the first abnormal deterioration criterion index among a plurality of abnormal deterioration criterion indices (S140) when the inter-cell voltage deviation is abnormal (Yes in S130).

In this case, when the inter-cell voltage deviation is included in the first abnormal deterioration criterion index, the present disclosure may check the BMS estimated SOH value (S220), may calculate the battery durability level using the formula consisting of L=100*(SOH−70)/30 (where L is the battery durability level and is based on BOL (Beginning Of Life) 100% to EOL (End Of Life) 70%) (S230), and may diagnose the battery durability level as the abnormal deterioration mid-term level L3 based on the calculation result (S240).

In addition, the present disclosure may determine whether the inter-cell voltage deviation is included in the second abnormal deterioration criterion index among the plurality of abnormal deterioration criterion indices (S150) when the inter-cell voltage deviation is not included in the first abnormal deterioration criterion index (No in S140).

In this case, when the inter-cell voltage deviation is included in the second abnormal deterioration criterion index, the present disclosure may check the BMS estimated SOH value (S250), may calculate the battery durability level using the formula consisting of L=100*(SOH−70)/30 (where L is the battery durability level and is based on BOL (Beginning Of Life) 100% to EOL (End Of Life) 70%) (S260), and may diagnose the battery durability level as the abnormal deterioration terminal level L4 based on the calculation result (S270).

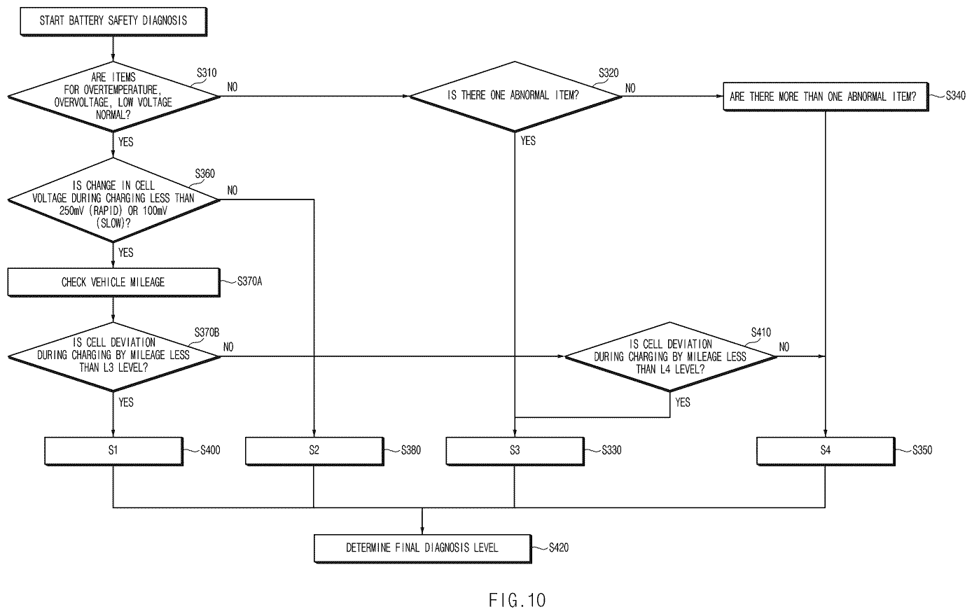

As illustrated in FIG. 10, the battery safety diagnosis method of the present disclosure is described in more detail as follows.

As illustrated in FIG. 10, the present disclosure may determine whether the first diagnostic condition for the overtemperature diagnostic item, the overvoltage diagnostic item, and the low voltage diagnostic item among the plurality of safety diagnostic items is satisfied when the battery safety diagnosis starts (S310).

Next, the present disclosure may determine whether the second diagnostic condition for the cell voltage change item during charging among the plurality of safety diagnostic items is satisfied (S360) when all of the first diagnostic conditions are satisfied (Yes in S310).

In this case, the present disclosure may determine whether the second diagnostic condition for the cell voltage change item during charging is satisfied, which has the diagnostic condition that the individual cell voltage is less than about 250 mV during rapid charging or the individual cell voltage is less than about 100 mV during slow charging.

Next, the present disclosure may determine the battery safety level as the abnormal deterioration initial level S2 when the second diagnostic condition is not satisfied (S380).

In addition, the present disclosure may check the vehicle mileage when the second diagnostic condition is satisfied (S370A), and determine whether the third diagnostic condition is satisfied for the inter-cell voltage deviation item during charging corresponding to the checked vehicle mileage (S370B).

In this case, the present disclosure may determine whether the condition is satisfied that the cell voltage deviation during charging corresponding to the checked vehicle mileage is less than the first cell deviation reference voltage (S370B).

For example, when determining whether the condition of being less than the first cell deviation reference voltage is satisfied, the present disclosure may determine that the condition of being less than the first cell deviation reference voltage is satisfied when any one of the following is satisfied: a first condition in which the inter-cell voltage deviation corresponding to the vehicle mileage is less than 60 mV in a section of 0 to less than 50,000 km, a second condition in which the inter-cell voltage deviation is less than 90 mV in a section of 50,000 km to less than 100,000 km, a third condition in which the inter-cell voltage deviation is less than 120 mV in a section of 100,000 km to less than 200,000 km, and a fourth condition in which the inter-cell voltage deviation is less than 200 mV in a section of 200,000 km to less than 300,000 km.

Next, the present disclosure may determine the battery safety level as a normal deterioration level (S400) when the condition of being less than the first cell deviation reference voltage among the third diagnostic conditions is satisfied (Yes in S370B).

In addition, the present disclosure may determine whether the condition that the cell voltage deviation during charging corresponding to the vehicle mileage is less than the second cell deviation reference voltage is satisfied (S410) when the condition that the first cell deviation reference voltage is less than the first cell deviation reference voltage is not satisfied (No in S370B).

For example, when determining whether the condition of being less than the second cell deviation reference voltage is satisfied, the present disclosure may determine that the condition of being less than the second cell deviation reference voltage is satisfied when any one of the following is satisfied: a fifth condition in which the inter-cell voltage deviation corresponding to the vehicle mileage is less than 90 mV in a section of 0 to less than 50,000 km, a sixth condition in which the inter-cell voltage deviation is less than 120 mV in a section of 50,000 km to less than 100,000 km, a seventh condition in which the inter-cell voltage deviation is less than 150 mV in a section of 100,000 km to less than 200,000 km, and an eighth condition in which the inter-cell voltage deviation is less than 250 mV in a section of 200,000 km to less than 300,000 km.

Next, the present disclosure may determine the battery safety level as the abnormal deterioration mid-term level S3 (S330) when the condition of being less than the second cell deviation reference voltage among the third diagnostic conditions is satisfied (Yes in S410).

In addition, the present disclosure may determine the battery safety level as the abnormal deterioration terminal level S4 (S350) when the condition of being less than the second cell deviation reference voltage among the third diagnostic conditions is not satisfied (No in S410).

The present disclosure may determine whether there is a diagnostic item that does not satisfy the first diagnostic condition as a result of determining whether the first diagnostic condition is satisfied for the overtemperature diagnostic item, the overvoltage diagnostic item, and the low voltage diagnostic item (S310).

As an example, when determining whether the first diagnostic condition is satisfied, the present disclosure may determine whether the first diagnostic condition is satisfied for the overtemperature diagnostic item having the diagnostic condition that a maximum temperature Tmax is less than about 60 degrees, the overvoltage diagnostic item having the diagnostic condition that a maximum voltage Vmax is less than about 4.2 V, and the low voltage diagnostic item having the diagnostic condition that a minimum voltage Vmin is more than about 2.0 V.

Next, the present disclosure may determine whether the number of diagnostic items that do not satisfy the first diagnostic condition is “1” (S320) when there is a diagnostic item that does not satisfy the first diagnostic condition (No in S310).

In this case, the present disclosure may determine the battery safety level as the abnormal deterioration mid-term level S3 (S330) when the number of diagnostic items that do not satisfy the first diagnostic condition is “1” (Yes in S320).

Next, the present disclosure may determine the battery safety level as the abnormal deterioration terminal level S4 (S350) when the number of diagnostic items that do not satisfy the first diagnostic condition exceeds “1” (S340).

As an example, when the maximum temperature Tmax is maintained at about 60 degrees or more for about 1 second or more, the present disclosure may recognize the diagnostic condition of the overtemperature diagnostic item as unsatisfactory, when the maximum voltage Vmax is maintained at about 4.3 V or more for about 1 second, the present disclosure may recognize the diagnostic condition of the overvoltage diagnostic item as unsatisfactory, and when the minimum voltage Vmin is maintained at about 2.0 V for about 1 second, the present disclosure may recognize the diagnostic condition of the low voltage diagnostic item as unsatisfactory.

In addition, the present disclosure may determine the final diagnosis level of the battery status based on the battery durability diagnosis level and the battery safety diagnosis level (S420).

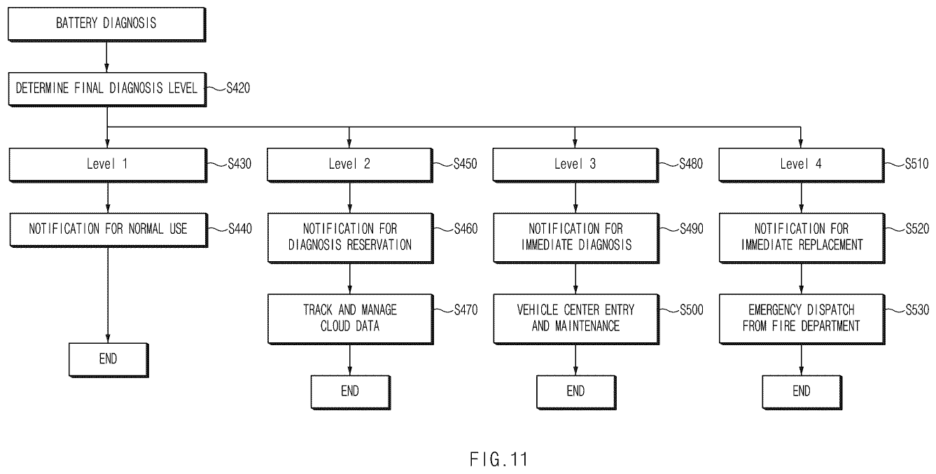

As illustrated in FIG. 11, the battery diagnostic final level determination method of the present disclosure is described in more detail as follows.

As illustrated in FIG. 11, when the battery diagnosis final level determination starts (S420), the present disclosure may determine the final diagnosis level of the battery status as the first level (S430) when both the battery durability diagnosis and the battery safety diagnosis are at a normal deterioration level, and may output a notification for normal battery use (S440).

Next, the present disclosure may determine the final diagnosis level of the battery status as the second level (S450) and may output a notification for battery diagnosis reservation (S460) when the battery durability diagnosis is at an abnormal deterioration level and the battery safety diagnosis is at a normal deterioration level or an abnormal deterioration initial level.

In this case, the present disclosure may output a notification for battery diagnosis reservation when the final diagnosis level of the battery status is at the second level (S460) and may track and manage the cloud data of the battery to be diagnosed (S470).

Next, the present disclosure may determine the final diagnosis level of the battery status as the third level when the battery durability diagnosis is the abnormal deterioration level and the battery safety diagnosis is the abnormal deterioration mid-term level (S480), and may output a notification for immediate battery diagnosis (S490).

In this case, the present disclosure may output a notification for immediate battery diagnosis when the final diagnosis level of the battery status is the third level (S490), and may request vehicle center entry and maintenance (S500).

In addition, the present disclosure may determine the final diagnosis level of the battery status as the fourth level when the battery durability diagnosis is an abnormal deterioration level and the battery safety diagnosis is an abnormal deterioration terminal level (S510), and may output a notification for immediate battery replacement (S520).

In this case, the present disclosure may output a notification for immediate battery replacement when the final diagnosis level of the battery status is the fourth level (S520) and may request emergency dispatch from the fire department (S530).

As in the above description, the present disclosure may diagnose the battery status based on the first diagnosis criterion index set for battery durability diagnosis and the second diagnosis criterion index set for battery safety diagnosis, thereby setting a wide diagnosis criterion range while setting a response strategy for each diagnosis section, and thereby enabling flexible customer response and reducing quality costs due to overdiagnosis.

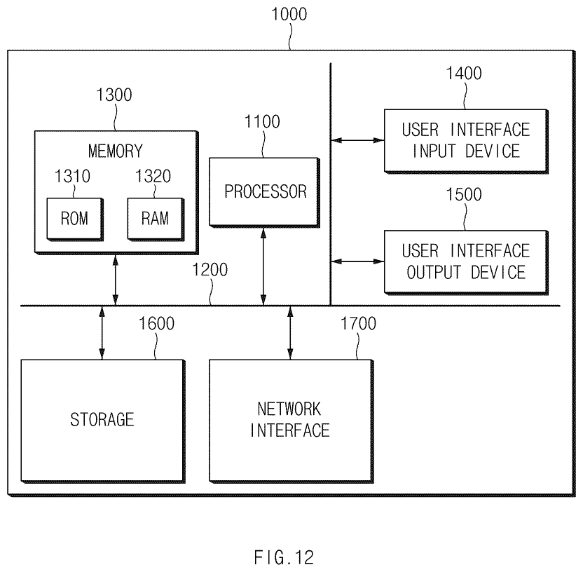

FIG. 12 illustrates a computing system in a vehicle, according to an embodiment of the present disclosure.

Referring to FIG. 12, a computing system 1000 may include at least one processor 1100, a memory 1300, a user interface input device 1400, a user interface output device 1500, storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read only memory (ROM) and a random access memory (RAM).

Accordingly, the operations of the method or algorithm described in connection with the embodiments disclosed in the specification may be directly implemented with a hardware module, a software module, or a combination of the hardware module and the software module, which is executed by the processor 1100. The software module may reside on a storage medium (i.e., the memory 1300 and/or the storage 1600) such as a random access memory (RAM), a flash memory, a read only memory (ROM), an erasable and programmable ROM (EPROM), an electrically EPROM (EEPROM), a register, a hard disk drive, a removable disc, or a compact disc-ROM (CD-ROM).

The storage medium as an example may be coupled to the processor 1100. The processor 1100 may read out information from the storage medium and may write information into the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

According to an embodiment of the present disclosure, the present disclosure may diagnose the battery status based on the first diagnosis criterion index set for battery durability diagnosis and the second diagnosis criterion index set for battery safety diagnosis, thereby setting a wide diagnosis criterion range while setting a response strategy for each diagnosis section, and thereby enabling flexible customer response and reducing quality costs due to overdiagnosis.

In addition to this, various effects identified directly or indirectly through this specification may be provided.

The above description is merely illustrative of the technical idea of the present disclosure, and those of ordinary skill in the art to which the present disclosure pertains should be able to make various modifications and variations without departing from the essential characteristics of the present disclosure.

Therefore, embodiments of the present disclosure are not intended to limit the technical spirit of the present disclosure, but provided only for the illustrative purpose. The scope of protection of the present disclosure should be construed by the attached claims, and all equivalents thereof should be construed as being included within the scope of the present disclosure.

What is claimed is:

1. A battery diagnosis apparatus comprising:
a memory configured to store a first diagnosis criterion index set for a battery durability diagnosis and a second diagnosis criterion index set for a battery safety diagnosis; and
a processor configured to diagnose a battery status based on the first diagnosis criterion index and the second diagnosis criterion index.

2. The battery diagnosis apparatus of claim 1, wherein the processor is further configured to:
obtain data of a battery to be diagnosed,
check a distribution of State of Health (SOH) parameters and an inter-cell voltage deviation from the data to perform the battery durability diagnosis based on the first diagnosis criterion index,
obtain data corresponding to a plurality of preset safety diagnostic items from the battery to be diagnosed,
perform the battery safety diagnosis based on the second diagnosis criterion index, and
determine a final diagnosis level of the battery status based on the battery durability diagnosis and the battery safety diagnosis.

3. The battery diagnosis apparatus of claim 2, wherein the processor is further configured to:
in obtaining the data of the battery to be diagnosed, obtain cloud data including vehicle mileage-specific SOH data of the battery to be diagnosed based on a diagnosis request of the battery being received.

4. The battery diagnosis apparatus of claim 2, wherein the processor is further configured to:
perform a first determination by first determining whether vehicle mileage-specific SOH data of the battery to be diagnosed is distributed within an average SOH percentile range by vehicle mileage,
perform a second determination by secondarily determining a status of an inter-cell voltage deviation of the battery to be diagnosed based on the first diagnosis criterion index and based on whether the vehicle mileage-specific SOH data is distributed within the average SOH percentile range by the vehicle mileage, and
determine a battery durability level based on results of the first determination and the second determination to perform the battery durability diagnosis based on the battery durability level.

5. The battery diagnosis apparatus of claim 4, wherein the processor is further configured to:
in performing the first determination, determine the battery durability level as a condition-satisfying deterioration level based on the vehicle mileage-specific SOH data being distributed within the average SOH percentile range by the vehicle mileage.

6. The battery diagnosis apparatus of claim 4, wherein the processor is further configured to:
based on the vehicle mileage-specific SOH data being distributed beyond the average SOH percentile range by the vehicle mileage, determine the battery durability level as a condition-failing deterioration level based on the first diagnosis criterion index including a plurality of preset condition-failing deterioration criterion indices to perform the second determination.

7. The battery diagnosis apparatus of claim 6, wherein the processor is further configured to:
in determining that the battery durability level as the condition-failing deterioration level,
determine whether the inter-cell voltage deviation of the battery to be diagnosed fails to satisfy a predetermined condition based on the vehicle mileage-specific SOH data being distributed beyond the average SOH percentile range by the vehicle mileage,
determine the battery durability level as a condition-failing deterioration initial level based on the inter-cell voltage deviation satisfying a predetermined inter-cell voltage deviation condition,
determine whether the inter-cell voltage deviation is included in a first condition-failing deterioration criterion index among the plurality of preset condition-failing deterioration criterion indices based on the inter-cell voltage deviation failing to satisfy the predetermined inter-cell voltage deviation condition,
determine the battery durability level as a condition-failing deterioration mid-term level based on the inter-cell voltage deviation being included in the first condition-failing deterioration criterion index,
determine whether the inter-cell voltage deviation is included in a second condition-failing deterioration criterion index among the plurality of preset condition-failing deterioration criterion indices based on the inter-cell voltage deviation being beyond the first condition-failing deterioration criterion index, and
determine the battery durability level as a condition-failing deterioration terminal level based on the inter-cell voltage deviation being included in the second condition-failing deterioration criterion index.

8. The battery diagnosis apparatus of claim 4, wherein the processor is further configured to:
in determining the battery durability level,
check a Battery Management System (BMS) estimated SOH value; and
determine the battery durability level based on a formula including L=100*(SOH−70)/30 where, L is the battery durability level and is based on Beginning Of Life (BOL) 100% to End Of Life (EOL) 70%.

9. The battery diagnosis apparatus of claim 2, wherein the processor is further configured to:
determine whether the data corresponding to the plurality of preset safety diagnostic items satisfies diagnostic conditions for the plurality of preset safety diagnostic items based on the second diagnosis criterion index;
determine a battery safety level based on one or more safety diagnostic items that fail to satisfy the diagnostic conditions; and
perform the battery safety diagnosis based on the determined battery safety level.

10. The battery diagnosis apparatus of claim 9, wherein the processor is further configured to:
determine whether first diagnostic conditions for an over-temperature diagnostic item, an over-voltage diagnostic item, and a low-voltage diagnostic item among the plurality of preset safety diagnostic items is satisfied;
first determine the battery safety level based on a number of one or more safety diagnostic items that fail to satisfy the first diagnostic condition;
based on all of the first diagnostic conditions being satisfied, determine whether a second diagnostic condition for a cell voltage change item during charging is satisfied and whether a third diagnostic condition for an inter-cell voltage deviation item during charging is satisfied; and
secondly determine the battery safety level based on one or more safety diagnostic items that fail to satisfy the second and third diagnostic conditions.

11. The battery diagnosis apparatus of claim 2, wherein the processor is further configured to:
determine the final diagnosis level of the battery status as a first level to output a notification for condition-satisfying battery use based on the battery durability diagnosis and the battery safety diagnosis being at a condition-satisfying deterioration level,
determine the final diagnosis level of the battery status as a second level to output a notification for battery diagnosis reservation based on the battery durability diagnosis being at a condition-failing deterioration level and the battery safety diagnosis being at the condition-satisfying deterioration level or a condition-failing deterioration initial level,
determine the final diagnosis level of the battery status as a third level to output a notification for battery immediate diagnosis based on the battery durability diagnosis being at the condition-failing deterioration level and the battery safety diagnosis being at a condition-failing deterioration mid-term level, and
determine the final diagnosis level of the battery status as a fourth level to output a notification for battery immediate replacement based on the battery durability diagnosis being at the condition-failing deterioration level and the battery safety diagnosis being at a condition failing deterioration terminal level.

12. A battery diagnosis method comprising:
obtaining data of a battery to be diagnosed;
checking a distribution of State of Health (SOH) parameters and an inter-cell voltage deviation from the data;
performing a battery durability diagnosis based on a first diagnosis criterion index;
obtaining data corresponding to a plurality of preset safety diagnostic items from the battery to be diagnosed;
performing a battery safety diagnosis based on a second diagnosis criterion index; and
determining a final diagnosis level of a battery status based on the battery durability diagnosis and the battery safety diagnosis.

13. The battery diagnosis method of claim 12, wherein obtaining the data of the battery to be diagnosed includes obtaining cloud data including vehicle mileage-specific SOH data of the battery to be diagnosed based on a diagnosis request for the battery being received.

14. The battery diagnosis method of claim 12, wherein performing the battery durability diagnosis includes:
performing a first determination by first determining whether vehicle mileage-specific SOH data of the battery to be diagnosed is distributed within an average SOH percentile range by vehicle mileage,
performing a second determination by secondarily determining a status of an inter-cell voltage deviation of the battery to be diagnosed based on the first diagnosis criterion index and based on whether the vehicle mileage-specific SOH data is distributed within the average SOH percentile range by the vehicle mileage, and
determining a battery durability level based on results of the first determination and the second determination to perform the battery durability diagnosis based on the battery durability level.

15. The battery diagnosis method of claim 14, wherein performing the first determination includes determining the battery durability level as a condition-satisfying deterioration level based on the vehicle mileage-specific SOH data being distributed within the average SOH percentile range by the vehicle mileage.

16. The battery diagnosis method of claim 14, wherein performing the second determination includes determining the battery durability level as a condition-failing deterioration level based on the first diagnosis criterion index including a plurality of preset condition-failing deterioration criterion indices based on the vehicle mileage-specific SOH data being distributed beyond the average SOH percentile range by the vehicle mileage.

17. The battery diagnosis method of claim 16, wherein determining the battery durability level as the condition-failing deterioration level includes:
determining whether the inter-cell voltage deviation of the battery to be diagnosed fails to satisfy a predetermined condition based on the vehicle mileage-specific SOH data being distributed beyond the average SOH percentile range by the vehicle mileage,
determining the battery durability level as a condition-failing deterioration initial level based on the inter-cell voltage deviation satisfying a predetermined inter-cell voltage deviation condition,
determining whether the inter-cell voltage deviation is included in a first condition-failing deterioration criterion index among the plurality of preset condition-failing deterioration criterion indices based on the inter-cell voltage deviation failing to satisfy the predetermined inter-cell voltage deviation condition,
determining the battery durability level as a condition-failing deterioration mid-term level based on the inter-cell voltage deviation being included in the first condition-failing deterioration criterion index,
determining whether the inter-cell voltage deviation is included in a second condition-failing deterioration criterion index among the plurality of preset condition-failing deterioration criterion indices based on the inter-cell voltage deviation being beyond the first condition-failing deterioration criterion index, and
determining the battery durability level a condition failing deterioration terminal level based on the inter-cell voltage deviation being included in the second condition-failing deterioration criterion index.

18. The battery diagnosis method of claim 14, wherein determining the battery durability level includes:
checking a Battery Management System (BMS) estimated SOH value; and
determining the battery durability level based on a formula including L=100*(SOH−70)/30 where, L is the battery durability level and is based on Beginning Of Life (BOL) 100% to End Of Life (EOL) 70%.

19. The battery diagnosis method of claim 12, wherein performing the battery safety diagnosis includes:
determining whether the data corresponding to the plurality of preset safety diagnostic items satisfies diagnostic conditions for the plurality of preset safety diagnostic items based on the second diagnosis criterion index;
determining a battery safety level based on one or more safety diagnostic items that fail to satisfy the diagnostic conditions, and
performing the battery safety diagnosis based on the determined battery safety level.

20. The battery diagnosis method of claim 19, wherein determining the battery safety level includes:
determining whether first diagnostic conditions for an over-temperature diagnostic item, an over-voltage diagnostic item, and a low-voltage diagnostic item among the plurality of preset safety diagnostic items is satisfied;
first determining the battery safety level based on a number of one or more safety diagnostic items that fail to satisfy the first diagnostic condition,
based on all of the first diagnostic conditions being satisfied, determining whether a second diagnostic condition for a cell voltage change item during charging is satisfied and whether a third diagnostic condition for an inter-cell voltage deviation item during charging is satisfied, and
secondly determining the battery safety level based on one or more safety diagnostic items that fail to satisfy the second and third diagnostic conditions.
